(19) United States
(12) Patent Application Publication
(10) Pub. No.: US 2008/0157237 A1
(43) Pub. Date: Jul. 3, 2008

(54) SWITCHING DEVICE AND METHOD OF FABRICATING THE SAME

(76) Inventor: Myung-Soo Kim, Gyeongsangnam-do (KR)

Correspondence Address: SHERR & NOURSE, PLLC, 620 HERNDON PARKWAY, SUITE 200, HERNDON, VA, 20170, US

(21) Appl. No.: 11/957,655

(22) Filed: Dec. 17, 2007

(30) Foreign Application Priority Data
Dec. 29, 2006 (KR) 10-2006-0137272

(51) Int. Cl. H01L 29/84; H01L 21/00

(52) U.S. Cl. 257/415; 438/52; 438/149; 257/E29.324; 257/E21.001

(57) ABSTRACT

A switching device having a construction that facilitates physical contact between the second terminal electrode and the first terminal electrode, thereby enabling the performance of turn-on. Embodiments do not require an impurity diffusion region nor performs switching action through the channel region so that can become highly integrated and thinness. Also, switching can be performed by way of the physical contact of the first terminal electrode and the second terminal electrode, thereby making it possible to improve turn on-off characteristics.

This application claims priority under 35 U.S.C. 119 to Korean Patent Application No. 10-2006-0137272 (filed on Dec. 29, 2006), which is hereby incorporated by reference in its entirety.

### BACKGROUND

A metal-oxide-semiconductor (MOS) transistor (MOSFET) may be used primarily as a switching device in an integrated circuit. The MOS transistor may lend several benefits in terms of ease of electrical control, high-integration and enhanced switching characteristics.

A MOS transistor may include a gate electrode for turning on/off a channel region in a semiconductor substrate may be formed on and/or over a gate insulation layer. The MOS transistor may also include a source region and a drain region, which are impurity diffusion regions formed in the semiconductor substrate on both sides of the gate electrode.

In obtaining a highly integrated MOS transistor, its switching characteristics may become deteriorated due to a single channel effect and narrow width effect. Accordingly, achieving further integration may become limited. Also, the source region and the drain region used as input/output terminals of a signal may be formed as a diffusion region by implanting impurities into the semiconductor substrate. Even still, the MOS transistor may have an adverse impact on switching characteristics such as junction breakdown, leakage current, and increases in area due to lateral diffusion of the impurities, etc. Therefore, there is a need for a switching device having a different structure.

### SUMMARY

Embodiments relate to a switching device that can include at least one of the following: a switching electrode formed over a semiconductor substrate; a first terminal electrode formed over the semiconductor substrate spaced apart from the switching electrode; and a second terminal electrode extending laterally over the semiconductor substrate including the switching electrode and the first terminal electrode. In accordance with embodiments, the second terminal has a first end that is fixedly supported and a second end that is not fixedly supported.

Embodiments relate to a switching device that can include a switching electrode formed over a semiconductor substrate; a first terminal electrode formed over the semiconductor substrate spaced apart from the switching electrode; and a second terminal electrode extending laterally over the semiconductor substrate including the switching electrode and the first terminal electrode. In accordance with embodiments, the second terminal can have a first end that is fixedly supported and a second end that is not fixedly supported.

Embodiments relate to a method of manufacturing a switching device that can include at least one of the following steps: forming a first metal layer over a semiconductor substrate; forming a second metal layer formed spaced apart laterally from the first metal layer over the semiconductor substrate; forming an elastic layer spaced apart vertically from and extending over the first metal layer and the second metal layer. In accordance with embodiments, the elastic layer can include a first end fixedly positioned and a second end not fixedly positioned.

### DRAWINGS

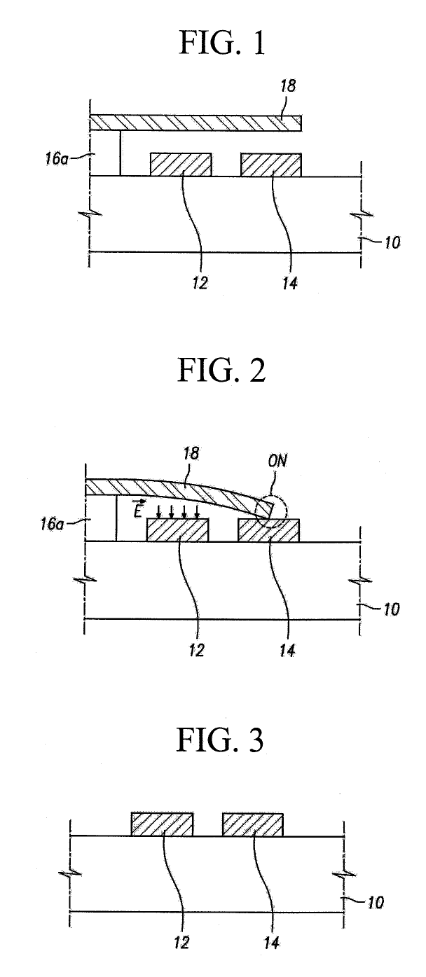

Example FIGS. 1 and 2 illustrate a switching device, in accordance with embodiments.

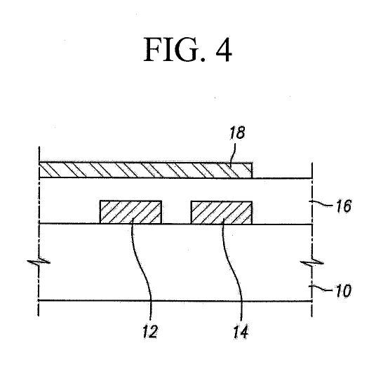

Example FIGS. 3 and 4 illustrate a method of fabricating a switching device, in accordance with embodiments.

### DESCRIPTION

As illustrated in example FIG. 1, a switching device in accordance with embodiments can include switching electrode 12 and first terminal electrode 14 spaced at a predetermined interval formed on and/or over semiconductor substrate 10. Switching electrode 12 and first terminal electrode 14 can be formed of a metal layer and connectable to wiring, respectively.

Second terminal electrode 18 can be positioned spaced at a predetermined interval vertically above first terminal electrode 14 and switching electrode 12. One end of second terminal electrode 18 can extend over switching electrode 12 and terminal electrode 14. On the other hand, a second end of second terminal electrode 18 can be fixedly positioned on and/or over support layer 16a formed on and/or over substrate 10.

As illustrated in example FIG. 2, second terminal electrode 18 can be composed of an elastic material such that it is free to be bent downwardly towards semiconductor substrate 10. In the switching device in accordance with embodiments, since second terminal electrode 18 can perform the switching operation by way of elasticity, second terminal electrode 18 can be formed of a thin metal film having elasticity.

In two opposed electric conductors, attractive force or repulsive force operates by way of charged electrical charges. The electric conductor can be positioned spaced at a predetermined interval and easily bent by way of attractive forces when charges having opposite polarity are accumulated. The attractive force can be maintained up to the time before the charges are discharged. The switching device in accordance with embodiments can apply voltage so that different charges can be accumulated in switching electrode 12 and second terminal electrode 18 using such a principle.

The attractive force can be generated between switching electrode 12 and second terminal electrode 18 using an electric field. When the attractive force is generated between switching electrode 12 and second terminal electrode 18, second terminal electrode 18 composed of an elastic material can be easily bent downwardly toward switching electrode 12. Since a first end of second terminal electrode 18 is supported by support layer 16a and the second end thereof is spaced above first terminal electrode 14, the second end can directly contact first terminal electrode 14. Thereby, first terminal electrode 14 and second terminal electrode 18 can be electrically conducted when connected.

Accordingly, the switching device in accordance with embodiments can obtain high integration and thinness by reducing the size of first terminal electrode 14 and switching electrode 12. Also, since first terminal electrode 14 and second terminal electrode 18 can be physically contacted to perform switching, the switching device in accordance with embodiments can have enhanced switching characteristics, as compared to a switching device (e.g., a MOS transistor) by way of channel formation.

As illustrated in example FIG. 3, a method of manufacturing a switching device in accordance with embodiments can include forming switching electrode 12 and first terminal electrode 14 on and/or over semiconductor substrate 10. Switching electrode 12 and first terminal electrode 14 can be formed of a conductive layer. Furthermore, it is preferable that switching electrode 12 and first terminal electrode 14 are composed of a metal material to obtain a fast response speed. Switching electrode 12 and first terminal electrode 14 can be formed by applying a patterning or a damascene process by means of a photolithographic process.

As illustrated in example FIG. 4, support layer 16 can then be formed on and/or over semiconductor substrate 10 including switching electrode 12 and first terminal electrode 14. Support layer 16 can be composed of a silicon insulation material and have a low dielectric constant in order that it can prevent loss of signal charges due to parasitic capacitance and signal delay.

A conductive film can then be formed and patterned on and/or over support layer 16 to form second terminal electrode 18. Second terminal electrode 18 can extend laterally over switching electrode 12 and first terminal electrode 14. An isotropic etching process may then be conducted on support layer 16.

The support layer 16 between first terminal electrode 14 and second terminal electrode 18 and also between switching electrode 12 and second terminal electrode 18 can then be removed by an etching process. Thereby, support layer 16a supporting second terminal electrode 18 is formed on and/or over semiconductor substrate 10 adjacent switching electrode 12. Moreover, space can be formed between second terminal electrode 18 and first terminal electrode 14 and also between second terminal electrode 18 and switching electrode 12.

The switching device in accordance with embodiments can include a second terminal electrode spaced vertically above the switching electrode and which is also made of an elastic material to enable bending of the second terminal electrode due to the attractive forces between the second terminal electrode and the switching electrode. Through such a construction, the second terminal electrode and the first terminal electrode are physically contacted, thereby making it possible to perform turn-on.

Unlike the MOS transistor, the switching device in accordance with embodiments neither uses an impurity diffusion region nor performs switching action through a channel region. Accordingly, it can achieve high integration and thinness. Moreover, the switching function can be performed by way of the physical contact of the first terminal electrode and the second terminal electrode, thereby making it possible to improve turn on-off characteristics.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a switching electrode formed over a semiconductor substrate;
a first terminal electrode formed over the semiconductor substrate spaced apart from the switching electrode; and
a second terminal electrode extending laterally over the semiconductor substrate including the switching electrode and the first terminal electrode, wherein the second terminal has a first end that is fixedly supported and a second end that is not fixedly supported.

2. The apparatus of claim 1, wherein a vertical gap of predetermined size is between the first terminal electrode and the second terminal electrode and also between the switching electrode and the second terminal electrode.

3. The apparatus of claim 1, wherein the second terminal electrode is composed of an elastic material.

4. The apparatus of claim 3, wherein electrical charges having different polarities supplied to the switching electrode and the second terminal electrode cause the second terminal electrode to bend towards the semiconductor substrate and also cause the second end of the second terminal electrode to directly contact the first terminal electrode.

5. The apparatus of claim 1, further comprising a support layer formed spaced apart laterally from the switching electrode over the semiconductor substrate.

6. The apparatus of claim 5, wherein, the first end of the second terminal electrode is fixedly supported by the support layer.

7. The apparatus of claim 6, wherein the support layer comprises an insulation layer.

8. An apparatus comprising:
a first metal layer formed over a semiconductor substrate;
a second metal layer formed spaced apart laterally from the first metal layer over the semiconductor substrate;
an elastic layer formed spaced apart vertically from and extending over the first metal layer and the second metal layer, the elastic layer including a first end fixedly supported and a second end not fixedly supported.

9. The apparatus of claim 8, wherein the first metal layer comprises a switching electrode, the second metal layer comprises a first terminal electrode, and the elastic layer comprises a second terminal electrode.

10. The apparatus of claim 9, wherein the second terminal electrode is composed of an elastic material.

11. The apparatus of claim 10, wherein the elastic material comprises a metal material.

12. The apparatus of claim 11, wherein electrical charges having different polarities supplied to the switching electrode and the second terminal electrode cause the second terminal electrode to bend towards the semiconductor substrate and also cause the second end of the second terminal electrode to directly contact the first terminal electrode.

13. The apparatus of claim 8, further comprising an insulation layer formed spaced apart laterally from the first metal layer over the semiconductor substrate, wherein the insulation layer fixedly supports the first end of the elastic layer.

14. The apparatus of claim 13, wherein the insulation layer comprises a material having a low dielectric constant.

15. The apparatus of claim 14, wherein the insulation layer comprises a silicon material.

16. A method comprising:
forming a first metal layer over a semiconductor substrate;
forming a second metal layer formed spaced apart laterally from the first metal layer over the semiconductor substrate;
forming an elastic layer spaced apart vertically from and extending over the first metal layer and the second metal layer,
wherein the elastic layer includes a first end fixedly positioned and a second end not fixedly positioned.

17. The method of claim 16, wherein the first metal layer comprises a switching electrode, the second metal layer comprises a first terminal electrode, and the elastic layer comprises a second terminal electrode.

18. The method of claim 17, wherein the second terminal electrode is composed of an elastic material.

19. The method of claim 18, wherein the elastic material comprises a metal material.

20. The method of claim 19, wherein charges having different polarities supplied to the switching electrode and the second terminal electrode causes the second terminal electrode to bend towards the semiconductor substrate and also causes the second end of the second terminal electrode to directly contact the first terminal electrode.
